(19) United States
(12) Patent Application Publication
(10) Pub. No.: US 2016/0079547 A1
(43) Pub. Date: Mar. 17, 2016

(54) BLUE LUMINESCENT COMPOUNDS

(71) Applicant: E. I. DU PONT DE NEMOURS AND COMPANY, Wilmington, DE (US)

(72) Inventors: Kyung-Ho Park, Wilmington, DE (US); Ying Wang, West Chester, PA (US)

(21) Appl. No.: 14/784,506

(22) PCT Filed: Apr. 21, 2014
(86) PCT No.: PCT/US14/34792

§ 371 Date: Oct. 14, 2015

Related U.S. Application Data
(60) Provisional application No. 61/814,971, filed on Apr. 23, 2013.

(51) Int. Cl. H01L 51/00; C09K 11/06; C09K 11/02; C07F 15/00

(52) U.S. Cl. CPC H01L 51/0085; C07F 15/0033; H01L 51/0094; C09K 11/06; C09K 11/025; C09K 2211/185; C09K 2211/1044; C09K 2211/1007; H01L 51/0074; H01L 51/0073; H01L 51/5004

(57) ABSTRACT

There is provided a compound having Formula I

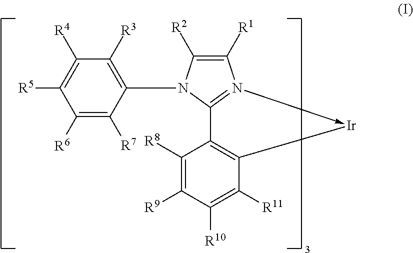

In Formula I: R¹, R², R⁴, R⁶, and R⁸-R¹¹ are the same or different and can be H, D, alkyl, deuterated alkyl, silyl, or deuterated silyl; R³ and R⁷ can be alkyl, deuterated alkyl, aryl, deuterated aryl, silyl, or deuterated silyl; R⁵ can be H, D, alkyl, deuterated alkyl, silyl, deuterated silyl, aryl, or deuterated aryl; and R³ is not the same as R⁷.

### RELATED APPLICATION DATA

This application claims priority under 35 U.S.C. §119(e) from U.S. Provisional Application No. 61/814,971, filed on Apr. 23, 2013, which is incorporated by reference herein in its entirety.

### BACKGROUND INFORMATION

1. Field of the Disclosure

This disclosure relates in general to blue luminescent compounds and their use in electronic devices.

2. Description of the Related Art

Organic electronic devices that emit light, such as light-emitting diodes that make up displays, are present in many different kinds of electronic equipment. In all such devices, an organic active layer is sandwiched between two electrical contact layers. At least one of the electrical contact layers is light-transmitting so that light can pass through the electrical contact layer. The organic active layer emits light through the light-transmitting electrical contact layer upon application of electricity across the electrical contact layers.

It is well known to use organic electroluminescent compounds as the active component in light-emitting diodes. Simple organic molecules, such as anthracene, thiadiazole derivatives, and coumarin derivatives are known to show electroluminescence. Metal complexes, particularly iridium and platinum complexes are also known to show electroluminescence. In some cases these small molecule compounds are present as a dopant in a host material to improve processing and/or electronic properties.

There is a continuing need for new luminescent compounds.

### SUMMARY

There is provided a material having Formula I

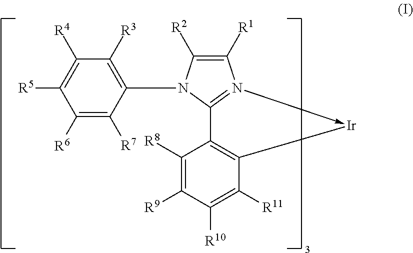

wherein:
R¹, R², R⁴, R⁶, and R⁸-R¹¹ are the same or different and are selected from the group consisting of H, D, alkyl, deuterated alkyl, silyl, and deuterated silyl;
R³ and R⁷ are selected from the group consisting of alkyl, deuterated alkyl, aryl, deuterated aryl, silyl, and deuterated silyl;
R⁵ is selected from the group consisting of H, D, alkyl, deuterated alkyl, silyl, deuterated silyl, aryl, and deuterated aryl;
with the proviso that R³ is not the same as R⁷.

There is also provided an organic electronic device comprising a first electrical contact, a second electrical contact and a photoactive layer therebetween, the photoactive layer comprising the material having Formula I.

The foregoing general description and the following detailed description are exemplary and explanatory only and are not restrictive of the invention, as defined in the appended claims.

### BRIEF DESCRIPTION OF THE DRAWINGS

Embodiments are illustrated in the accompanying figures to improve understanding of concepts as presented herein.

FIG. 1 includes an illustration of an organic light-emitting device.

FIG. 2 includes another illustration of an organic light-emitting device.

Skilled artisans appreciate that objects in the figures are illustrated for simplicity and clarity and have not necessarily been drawn to scale. For example, the dimensions of some of the objects in the figures may be exaggerated relative to other objects to help to improve understanding of embodiments.

### DETAILED DESCRIPTION

Many aspects and embodiments have been described above and are merely exemplary and not limiting. After reading this specification, skilled artisans appreciate that other aspects and embodiments are possible without departing from the scope of the invention.

Other features and benefits of any one or more of the embodiments will be apparent from the following detailed description, and from the claims. The detailed description first addresses Definitions and Clarification of Terms followed by the Material Having Formula I, Synthesis, Devices, and finally Examples.

### 1. Definitions and Clarification of Terms

Before addressing details of embodiments described below, some terms are defined or clarified.

The term “alkyl” is intended to mean a group derived from an aliphatic hydrocarbon and includes a linear, a branched, or a cyclic group. In some embodiments, an alkyl has from 1-20 carbon atoms.

The term “anti-quenching” when referring to a layer or material, refers to such layer or material which prevents quenching of luminance by the electron transport layer, either via an energy transfer or an electron transfer process.

The term “aromatic compound” is intended to mean an organic compound comprising at least one unsaturated cyclic group having delocalized pi electrons.

The term “aryl” is intended to mean a group derived from an aromatic hydrocarbon having one point of attachment. The term includes groups which have a single ring and those which have multiple rings which can be joined by a single bond or fused together. The term is intended to include heteroaryls. The term “alkylaryl” is intended to mean an aryl group having one or more alkyl substituents.

The term “charge transport,” when referring to a layer, material, member, or structure is intended to mean such layer, material, member, or structure facilitates migration of such charge through the thickness of such layer, material, member, or structure with relative efficiency and small loss of charge. Hole transport materials facilitate positive charge; electron transport materials facilitate negative charge. Although light-emitting materials may also have some charge transport properties, the term “charge transport layer, material, member, or structure” is not intended to include a layer, material, member, or structure whose primary function is light emission.

The term “deuterated” is intended to mean that at least one hydrogen (“H”) has been replaced by deuterium (“D”). The term “deuterated analog” refers to a structural analog of a compound or group in which one or more available hydrogens have been replaced with deuterium. In a deuterated compound or deuterated analog, the deuterium is present in at least 100 times the natural abundance level.

The term “dopant” is intended to mean a material, within a layer including a host material, that changes the electronic characteristic(s) or the targeted wavelength(s) of radiation emission, reception, or filtering of the layer compared to the electronic characteristic(s) or the wavelength(s) of radiation emission, reception, or filtering of the layer in the absence of such material.

The prefix “hetero” indicates that one or more carbon atoms have been replaced with a different atom. In some embodiments, the different atom is N, O, or S.

The term “host material” is intended to mean a material, usually in the form of a layer, to which a dopant may be added. The host material may or may not have electronic characteristic(s) or the ability to emit, receive, or filter radiation.

The terms “luminescent material”, “emissive material” and “emitter” are intended to mean a material that emits light when activated by an applied voltage (such as in a light-emitting diode or light-emitting electrochemical cell). The term “blue luminescent material” is intended to mean a material capable of emitting radiation that has an emission maximum at a wavelength in a range of approximately 445-490 nm. The term “green luminescent material” is intended to mean a material capable of emitting radiation that has an emission maximum at a wavelength in a range of approximately 495-570 nm. The term “orange luminescent material” is intended to mean a material capable of emitting radiation that has an emission maximum at a wavelength in a range of approximately 590-620 nm. The term “red luminescent material” is intended to mean a material capable of emitting radiation that has an emission maximum at a wavelength in a range of approximately 620-750 nm. The term “yellow luminescent material” is intended to mean a material capable of emitting radiation that has an emission maximum at a wavelength in a range of approximately 570-590 nm.

The term “layer” is used interchangeably with the term “film” and refers to a coating covering a desired area. The term is not limited by size. The area can be as large as an entire device or as small as a specific functional area such as the actual visual display, or as small as a single sub-pixel. Layers and films can be formed by any conventional deposition technique, including vapor deposition, liquid deposition (continuous and discontinuous techniques), and thermal transfer. Continuous deposition techniques, include but are not limited to, spin coating, gravure coating, curtain coating, dip coating, slot-die coating, spray coating, and continuous nozzle coating or printing. Discontinuous deposition techniques include, but are not limited to, ink jet printing, gravure printing, and screen printing.

The term “organic electronic device” or sometimes just “electronic device” is intended to mean a device including one or more organic semiconductor layers or materials.

The term “photoactive” refers to a material or layer that emits light when activated by an applied voltage (such as in a light emitting diode or chemical cell) or responds to radiant energy and generates a signal with or without an applied bias voltage (such as in a photodetector or a photovoltaic cell).

The term “secondary alkyl” refers to an alkyl group that is attached via a carbon which is bonded to two other carbons. Secondary alkyls including monocyclic alkyls.

The term “tertiary alkyl” refers to an alkyl group that is attached via a carbon which is bonded to three other carbons.

All groups may be unsubstituted or substituted. The substituent groups are discussed below.

In this specification, unless explicitly stated otherwise or indicated to the contrary by the context of usage, where an embodiment of the subject matter hereof is stated or described as comprising, including, containing, having, being composed of or being constituted by or of certain features or elements, one or more features or elements in addition to those explicitly stated or described may be present in the embodiment. An alternative embodiment of the disclosed subject matter hereof, is described as consisting essentially of certain features or elements, in which embodiment features or elements that would materially alter the principle of operation or the distinguishing characteristics of the embodiment are not present therein. A further alternative embodiment of the described subject matter hereof is described as consisting of certain features or elements, in which embodiment, or in insubstantial variations thereof, only the features or elements specifically stated or described are present.

Also, use of “a” or “an” are employed to describe elements and components described herein. This is done merely for convenience and to give a general sense of the scope of the invention. This description should be read to include one or at least one and the singular also includes the plural unless it is obvious that it is meant otherwise.

Group numbers corresponding to columns within the Periodic Table of the elements use the “New Notation” convention as seen in the CRC Handbook of Chemistry and Physics, 81^{st} Edition (2000-2001).

Unless otherwise defined, all technical and scientific terms used herein have the same meaning as commonly understood by one of ordinary skill in the art to which this invention belongs. Although methods and materials similar or equivalent to those described herein can be used in the practice or testing of embodiments of the present invention, suitable methods and materials are described below. All publications, patent applications, patents, and other references mentioned herein are incorporated by reference in their entirety, unless a particular passage is cited In case of conflict, the present specification, including definitions, will control. In addition, the materials, methods, and examples are illustrative only and not intended to be limiting.

To the extent not described herein, many details regarding specific materials, processing acts, and circuits are conventional and may be found in textbooks and other sources within the organic light-emitting diode display, photodetector, photovoltaic cell, and semiconductive member arts.

### 2. Compounds having Formula I

The new compounds described herein have Formula I

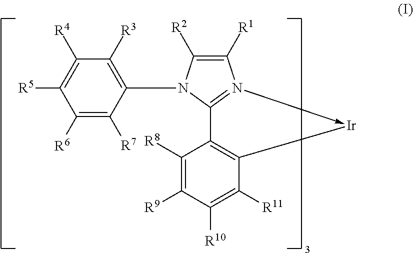

wherein:
R¹, R², R⁴, R⁶, and R⁸-R¹¹ are the same or different and are selected from the group consisting of H, D, alkyl, deuterated alkyl, silyl, and deuterated silyl;
R³ and R⁷ are selected from the group consisting of alkyl, deuterated alkyl, aryl, deuterated aryl, silyl, and deuterated silyl;
R⁵ is selected from the group consisting of H, D, alkyl, deuterated alkyl, silyl, deuterated silyl, aryl, and deuterated aryl;
with the proviso that R³ is not the same as R⁷.

In some embodiments, the compounds having Formula I are useful as emissive materials. In some embodiments, the compounds are blue emissive materials. They can be used alone or as a dopant in a host material.

The compounds having Formula I are soluble in many commonly used organic solvents. Solutions of these compounds can be used for liquid deposition using techniques such as discussed above. Unexpectedly, it has been found that the compounds having the substitution pattern shown in Formula I have improved efficiencies in devices. One measure of efficiency of OLED devices is the turn-on voltage, the voltage that must be applied to the stack to cause the start of significant light emission. The lower the turn-on voltage, the more efficient the device. Surprisingly, the compounds having Formula I, where R³ and R⁷ are different, can be used to prepare OLED devices with turn-on voltages that are lower than OLED devices made with previously described blue emitters where R³=R⁷. This is advantageous for reducing energy consumption in all types of devices, and particularly for lighting applications. Higher efficiency also improves device lifetime at constant luminance.

Specific embodiments of the present invention include, but are not limited to, the following.

### Embodiment 1

The compound of Formula I, wherein the compound is deuterated.

### Embodiment 2

The compound of Formula I, wherein the compound is at least 10% deuterated. By “% deuterated” or “% deuteration” is meant the ratio of deuterons to the total of hydrogens plus deuterons, expressed as a percentage. The deuteriums may be on the same or different groups.

### Embodiment 3

The compound of Formula I, wherein the compound is at least 25% deuterated.

### Embodiment 4

The compound of Formula I, wherein the compound is at least 50% deuterated.

### Embodiment 5

The compound of Formula I, wherein the compound is at least 75% deuterated.

### Embodiment 6

The compound of Formula I, wherein the compound is at least 90% deuterated.

### Embodiment 7

The compound of Formula I, wherein R¹ and R² are H or D.

### Embodiment 8

The compound of Formula I, wherein R³ is a secondary alkyl or deuterated secondary alkyl having 3-12 carbons.

### Embodiment 9

The compound of Formula I, wherein R³ is a secondary alkyl or deuterated secondary alkyl having 3-8 carbons.

### Embodiment 10

The compound of Formula I, wherein R³ is selected from the group consisting of 2-propyl, 2-butyl, 2-pentyl, cyclohexyl, methylcyclohexyl, and deuterated analogs thereof.

### Embodiment 11

The compound of Formula I, wherein R³ is a hydrocarbon aryl or deuterated hydrocarbon aryl having 6-20 ring carbons.

### Embodiment 12

The compound of Formula I, wherein R³ is a hydrocarbon aryl or deuterated hydrocarbon aryl having 6-12 ring carbons.

### Embodiment 13

The compound of Formula I, wherein R³ is a hydrocarbon aryl or deuterated hydrocarbon aryl having one or more substituents which are alkyl or deuterated alkyl groups having 1-10 carbons.

### Embodiment 14

The compound of Formula I, wherein R³ is a hydrocarbon aryl or deuterated hydrocarbon aryl having one or more substituents which are silyl or deuterated silyl groups.

### Embodiment 15

The compound of Formula I, according to embodiment 14, wherein the silyl groups are trimethylsilyl.

### Embodiment 16

The compound of Formula I, according to embodiment 14, wherein the silyl groups are triphenylsilyl.

### Embodiment 17

The compound of Formula I, wherein R³ is selected from phenyl, substituted phenyl, biphenyl, substituted biphenyl, and deuterated analogs thereof.

### Embodiment 18

The compound of Formula I, wherein R³ is selected from phenyl, phenyl substituted with one or more alkyl groups of 1-6 carbons, and deuterated analogs thereof.

### Embodiment 19

The compound of Formula I, wherein R⁴ is an alkyl or deuterated alkyl having 1-20 carbons.

### Embodiment 20

The compound of Formula I, wherein R⁴ is a silyl group selected from trimethylsilyl, triphenylsilyl, or a deuterated analog thereof.

### Embodiment 21

The compound of Formula I, wherein R⁴ is H or D.

### Embodiment 22

The compound of Formula I, wherein R⁵ is an alkyl or deuterated alkyl having 1-20 carbons.

### Embodiment 23

The compound of Formula I, wherein R⁵ is a silyl group selected from trimethylsilyl, triphenylsilyl, or a deuterated analog thereof.

### Embodiment 24

The compound of Formula I, wherein R⁵ is a hydrocarbon aryl or deuterated hydrocarbon aryl having 6-20 ring carbons.

### Embodiment 25

The compound of Formula I, wherein R⁵ is selected from the group consisting of phenyl, biphenyl, naphthyl, and deuterated analogs thereof, wherein any of the previous groups may have one or more substituents that are alkyl groups with 1-10 carbons.

### Embodiment 26

The compound of Formula I, wherein R⁵ is selected from the group consisting of phenyl, phenyl substituted with one or more alkyl groups having 1-6 carbons, and deuterated analogs thereof.

### Embodiment 27

The compound of Formula I, wherein R⁵ is H or D.

### Embodiment 28

The compound of Formula I, wherein R⁶ is an alkyl or deuterated alkyl having 1-20 carbons.

### Embodiment 29

The compound of Formula I, wherein R⁶ is a silyl group selected from trimethylsilyl, triphenylsilyl, or a deuterated analog thereof.

### Embodiment 30

The compound of Formula I, wherein R⁶ is H or D.

### Embodiment 31

The compound of Formula I, wherein R⁷ is a secondary alkyl or deuterated secondary alkyl having 3-12 carbons.

### Embodiment 32

The compound of Formula I, wherein R⁷ is a secondary alkyl or deuterated secondary alkyl having 3-8 carbons.

### Embodiment 33

The compound of Formula I, wherein R⁷ is selected from the group consisting of 2-propyl, 2-butyl, 2-pentyl, cyclohexyl, methylcyclohexyl, and deuterated analogs thereof.

### Embodiment 34

The compound of Formula I, wherein one of R⁷ is a hydrocarbon aryl or deuterated hydrocarbon aryl having 6-20 ring carbons.

### Embodiment 35

The compound of Formula I, wherein R⁷ is a hydrocarbon aryl or deuterated hydrocarbon aryl having 6-12 ring carbons.

### Embodiment 36

The compound of Formula I, wherein R³ is a hydrocarbon aryl or deuterated hydrocarbon aryl having one or more substituents which are alkyl or deuterated alkyl groups having 1-10 carbons.

### Embodiment 37

The compound of Formula I, wherein R⁷ is a hydrocarbon aryl or deuterated hydrocarbon aryl having one or more substituents which are silyl or deuterated silyl groups.

### Embodiment 38

The compound of Formula I, according to embodiment 37, wherein the silyl groups are trimethylsilyl.

### Embodiment 39

The compound of Formula I, according to embodiment 37, wherein the silyl groups are triphenylsilyl.

### Embodiment 40

The compound of Formula I, wherein R⁷ is selected from phenyl, phenyl substituted with one or more alkyl groups of 1-6 carbons, and deuterated analogs thereof.

### Embodiment 41

The compound of Formula I, wherein R⁸ is an alkyl or deuterated alkyl having 1-20 carbons.

### Embodiment 42

The compound of Formula I, wherein R⁸ is a silyl group selected from trimethylsilyl, triphenylsilyl, or a deuterated analog thereof.

### Embodiment 43

The compound of Formula I, wherein R⁸ is H or D.

### Embodiment 44

The compound of Formula I, wherein R⁹ is an alkyl or deuterated alkyl having 1-20 carbons.

### Embodiment 45

The compound of Formula I, wherein R⁹ is a silyl group selected from trimethylsilyl, triphenylsilyl, or a deuterated analog thereof.

### Embodiment 46

The compound of Formula I, wherein R⁹ is H or D.

### Embodiment 47

The compound of Formula I, wherein R¹⁰ is an alkyl or deuterated alkyl having 1-20 carbons.

### Embodiment 48

The compound of Formula I, wherein R¹⁰ is a silyl group selected from trimethylsilyl, triphenylsilyl, or a deuterated analog thereof.

### Embodiment 49

The compound of Formula I, wherein R¹⁰ is H or D.

### Embodiment 50

The compound of Formula I, wherein R¹¹ is an alkyl or deuterated alkyl having 1-20 carbons.

### Embodiment 51

The compound of Formula I, wherein R¹¹ is a silyl group selected from trimethylsilyl, triphenylsilyl, or a deuterated analog thereof.

### Embodiment 52

The compound of Formula I, wherein R¹¹ is H or D.

### Embodiment 53

The compound of Formula I, wherein R³ is alkyl or deuterated alkyl and R⁷ is aryl or deuterated aryl.

### Embodiment 54

The compound of Formula I, wherein R³ is alkyl or deuterated alkyl and R⁷ is silyl or deuterated silyl.

### Embodiment 55

The compound of Formula I, wherein R³ is silyl or deuterated aryl and R⁷ is alkyl or deuterated alkyl.

### Embodiment 56

The compound of Formula I, wherein R³ is silyl or deuterated silyl and R⁷ is aryl or deuterated aryl.

### Embodiment 57

The compound of Formula I, wherein R³ is aryl or deuterated aryl and R⁷ is alkyl or deuterated alkyl.

### Embodiment 58

The compound of Formula I, wherein R³ is aryl or deuterated aryl and R⁷ is silyl or deuterated silyl.

### Embodiment 59

The compound of Formula I, wherein one of R³ and R⁷ is alkyl or deuterated alkyl, and the other of R³ and R⁷ is selected from the group consisting of silyl, hydrocarbon aryl, and deuterated analogs thereof.

### Embodiment 60

The compound of Formula I, wherein one of R³ and R⁷ is alkyl or deuterated alkyl having 3-12 carbons, and the other of R³ and R⁷ is a hydrocarbon aryl or deuterated hydrocarbon aryl having 6-18 ring carbons.

### Embodiment 61

The compound of Formula I, wherein one of R³ and R⁷ is alkyl or deuterated alkyl having 3-12 carbons, and the other of R³ and R⁷ is silyl or deuterated silyl.

### Embodiment 62

The compound of Formula I, wherein one of R³ and R⁷ is silyl or deuterated silyl, and the other of R³ and R⁷ is a hydrocarbon aryl or deuterated hydrocarbon aryl having 6-18 ring carbons.

### Embodiment 63

The compound of Formula I, wherein one of R³ and R⁷ is selected from the group consisting of phenyl, biphenyl, napthyl, and deuterated analogs thereof, wherein any of the previous groups may have one or more substituents that are alkyl groups with 1-10 carbons.

### Embodiment 64

The compound of Formula I, wherein at least one of R¹, R², R⁴-R⁶, and R⁸-R¹¹ is not H or D.

Any of the above embodiments can be combined with one or more of the other embodiments, so long as they are not mutually exclusive. For example, the embodiment in which R³ is a secondary alkyl or deuterated secondary alkyl having 3-12 carbons can be combined with the embodiment in which R⁷ is selected from the group consisting of phenyl, phenyl substituted with one or more alkyl groups of 1-6 carbons, and deuterated analogs thereof. The same is true for the other non-mutually-exclusive embodiments discussed above. The skilled person would understand which embodiments were mutually exclusive and would thus readily be able to determine the combinations of embodiments that are contemplated by the present application.

Examples of compounds having Formula I include, but are not limited to, compounds B1 through B12 shown below.

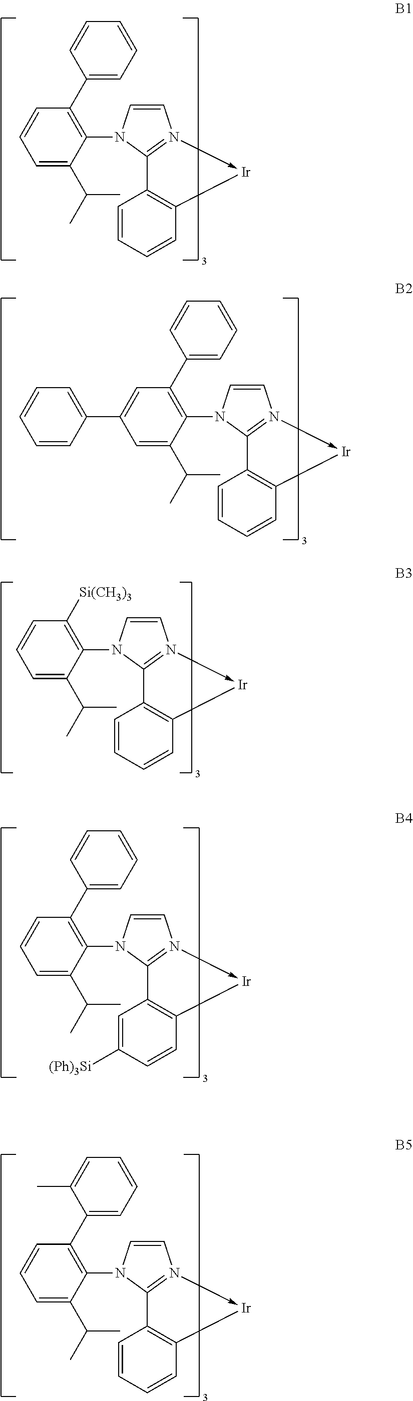

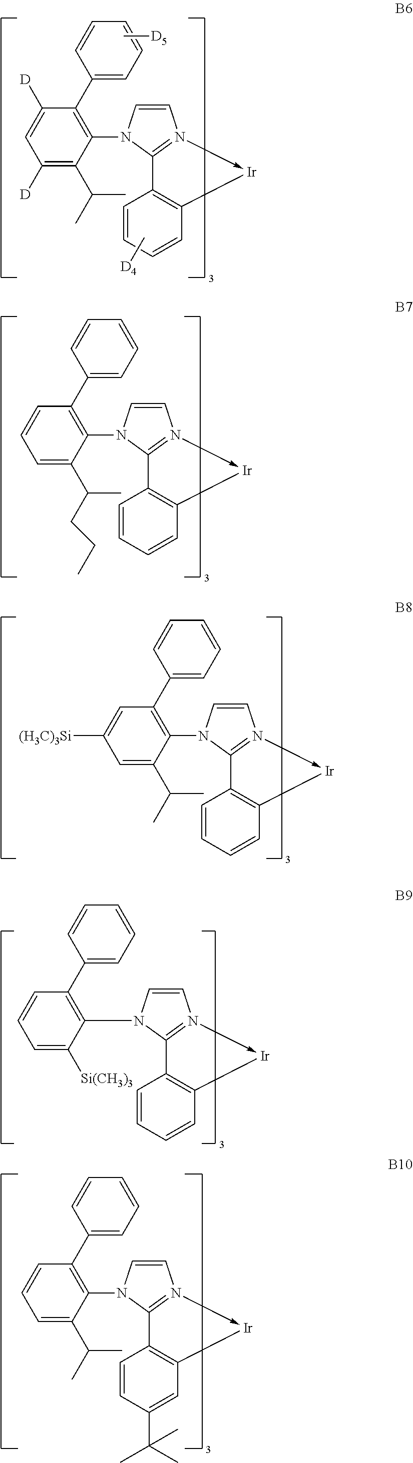

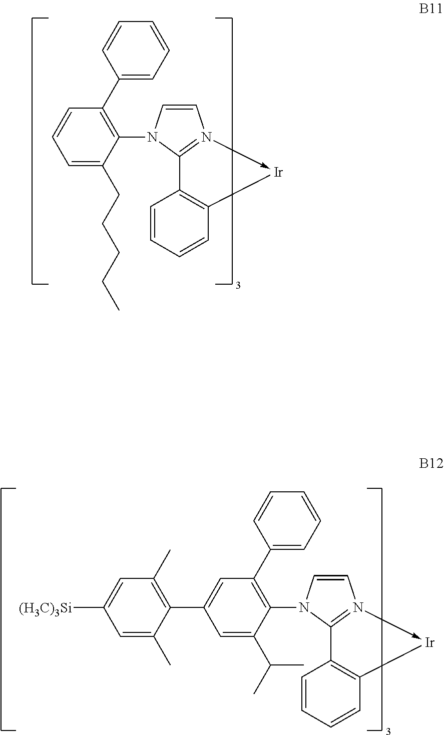

### 3. Synthesis

The phenyl-imidazole ligands can generally be made starting with substituted aniline compounds and reacting with benzoyl chloride or a substituted benzoyl chloride to form an intermediate amide. The amide is then reacted with either PCl₅/POCl₃ or simply SOCl₂ to provide imidoyl halide intermediate, which is in situ reacted with 2,2-dimethoxyethaneamine to form the substituted phenyl-imidazole compound. Details of the synthesis are given in the Examples.

The deuterated analog compounds can be prepared in a similar manner using deuterated precursor materials or, more generally, by treating the non-deuterated compound with deuterated solvent, such as d6-benzene, in the presence of a Lewis acid H/D exchange catalyst, such as aluminum trichloride or ethyl aluminum chloride, or acids such as CF₃COOD, DCl, etc. Deuteration reactions have also been described in published PCT application WO2011/053334.

There are many known methods for forming iridium complexes. In some embodiments, the phenyl-imidazole ligands are added to iridium acetylacetonate and reacted under pressure.

### 4. Devices

Organic electronic devices that may benefit from having one or more layers comprising the compounds having Formula I described herein include, but are not limited to, (1) devices that convert electrical energy into radiation (e.g., a light-emitting diode, light emitting diode display, lighting device, luminaire, or diode laser), (2) devices that detect signals through electronics processes (e.g., photodetectors, photoconductive cells, photoresistors, photoswitches, phototransistors, phototubes, IR detectors, biosensors), (3) devices that convert radiation into electrical energy, (e.g., a photovoltaic device or solar cell), and (4) devices that include one or more electronic components that include one or more organic semi-conductor layers (e.g., a transistor or diode).

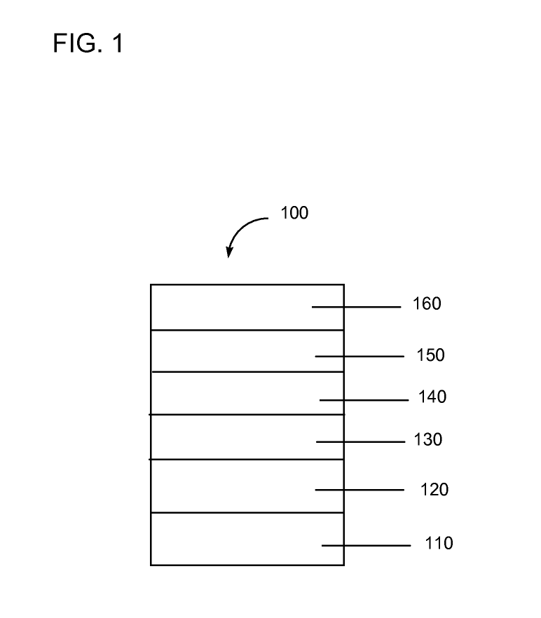

One illustration of an organic electronic device structure is shown in FIG. 1. The device 100 has a first electrical contact layer, an anode layer 110 and a second electrical contact layer, a cathode layer 160, and a photoactive layer 140 between them. Adjacent to the anode is a hole injection layer 120. Adjacent to the hole injection layer is a hole transport layer 130, comprising hole transport material. Adjacent to the cathode may be an electron transport layer 150, comprising an electron transport material. As an option, devices may have an anti-quenching layer (not shown) between the photoactive layer 140 and the electron transport layer 150. As a further option, devices may have an electron injection layer (not shown) between the electron transport layer 150 and the cathode 160. As a further option, devices may use one or more additional hole injection or hole transport layers (not shown) next to the anode 110 and/or one or more additional electron injection or electron transport layers (not shown) next to the cathode 160.

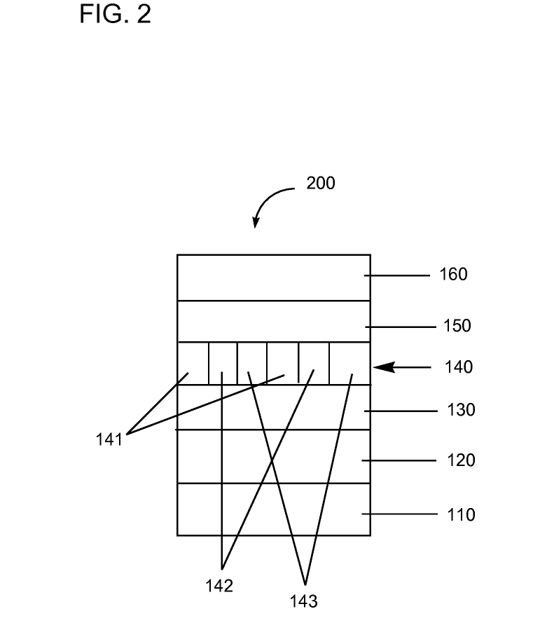

Layers 120 through 150, and any additional layers between them, are individually and collectively referred to as the active layers. In some embodiments, the photoactive layer is pixelated, as shown in FIG. 2. In device 200, layer 140 is divided into pixel or subpixel units 141, 142, and 143 which are repeated over the layer. Each of the pixel or subpixel units represents a different color. In some embodiments, the subpixel units are for red, green, and blue. Although three subpixel units are shown in the figure, two or more than three may be used.

In some embodiments, the different layers have the following range of thicknesses: anode 110, 500-5000 Å, in some embodiments, 1000-2000 Å; hole injection layer 120, 50-2000 Å, in some embodiments, 200-1000 Å; hole transport layer 130, 50-2000 Å, in some embodiments, 200-1000 Å; photoactive layer 140, 10-2000 Å, in some embodiments, 100-1000 Å; electron transport layer 150, 50-2000 Å, in some embodiments, 100-1000 Å; cathode 160, 200-10000 Å, in some embodiments, 300-5000 Å. In some embodiments, the optional anti-quenching layer has a thickness in the range of 50-2000 Å, in some embodiments, 100-1000 Å. In some embodiments, the optional electron injection layer has a thickness in the range of 1-100 Å; in some embodiments, 5-50 Å. The location of the electron-hole recombination zone in the device, and thus the emission spectrum of the device, can be affected by the relative thickness of each layer. The desired ratio of layer thicknesses will depend on the exact nature of the materials used.

In some embodiments, the compounds having Formula I are useful as the emissive material in photoactive layer 140, having blue emission color. They can be used alone or as a dopant in a host material.

a. Photoactive Layer

In some embodiments, the photoactive layer comprises a host material and a compound having Formula I as a dopant. In some embodiments, a second host material may be present. In some embodiments, the photoactive layer consists essentially of a host material and a compound having Formula I as a dopant. In some embodiments, the photoactive layer consists essentially of a first host material, a second host material, and a compound having Formula I as a dopant. The weight ratio of dopant to total host material is in the range of 5:95 to 70:30; in some embodiments, 10:90 to 20:80.

In some embodiments, the host has a triplet energy level higher than that of the dopant, so that it does not quench the emission. In some embodiments, the host is selected from the group consisting of carbazoles, indolocarbazoles, triazines, aryl ketones, phenylpyridines, pyrimidines, phenanthrolines, triarylamines, deuterated analogs thereof, combinations thereof, and mixtures thereof.

In some embodiments, the host is a carbazole-containing compound having Formula a

Ar(Cz)ₙ Formula a

where:
Ar is an aryl group, or a deuterated analog thereof;
Cz represents N-carbazolyl, diphenyl-N-carbazolyl, or a deuterated analog thereof; and
n is an integer from 1-4.

In some embodiments of Formula a, Ar is a hydrocarbon aryl having 6-50 ring carbons or a deuterated analog thereof. In some embodiments of Formula a, the hydrocarbon aryl or deuterated hydrocarbon aryl has one or more substituents selected from the group consisting of alkyl, silyl, and deuterated analogs thereof.

In some embodiments of Formula a, Ar is selected from the group consisting of biphenyl, terphenyl, naphthalene, triphenylene, phenanthrene, fluorene, chrysene, substituted analogs thereof, and deuterated analogs thereof.

In some embodiments of Formula a, Ar is a heteroaryl having 3-50 ring carbons or a deuterated analog thereof. In some embodiments of Formula a, the heteroaryl or deuterated heteroaryl has one or more substituents selected from the group consisting of alkyl, silyl, and deuterated analogs thereof.

In some embodiments of Formula a, Ar is selected from the group consisting of pyrazole, imidazole, triazole, oxazole, thiazole, oxadiazole, oxatriazole, dioxazole, thiadiazole, pyridine, pyridazine, pyrimidine, pyrazine, triazine, benzofuran, dibenzofuran, thiophene, dibenzothiophene, indole, benzimidazole, indazole, benzoxazole, benzisoxazole, benzothiazole, quinoline, isoquinoline, cinnoline, quinazoline quinoxaline, naphthyridine, phthalazine, pteridine, xanthene, phenothiazine, phenoxazine, benzofuropyridine, furodipyridine, benzothienopyridine, theinopdipyridine, substituted analogs thereof, and deuterated analogs thereof.

In some embodiments of Formula a, Ar is selected from the group consisting of biphenyl, terphenyl, triphenylene, phenanthrene, fluorene, chrysene, dibenzothiophene, dibenzofuran, pyridine, pyridazine, pyridmidine, pyrazine, triazine, benzimidazole, benzothiazole, quinoline, isoquinoline, benzofuropyridein, furodipyridine, benzothienopyridie, thienodipyridine, and deuterated analogs thereof.

In some embodiments of Formula a, n=2.

In some embodiments, the photoactive layer is intended to emit white light.

In some embodiments, the photoactive layer comprises a host, a compound of Formula I, and one or more additional dopants emitting different colors, so that the overall emission is white.

In some embodiments, the photoactive layer consists essentially of a host, a first dopant having Formula I, and a second dopant, where the second dopant emits a different color than the first dopant.

In some embodiments, the emission color of the second dopant is yellow.

In some embodiments, the photoactive layer consists essentially of a host, a first dopant having Formula I, a second dopant, and a third dopant.

In some embodiments, the emission color of the second dopant is red and the emission color of the third dopant is green.

Any kind of electroluminescent (“EL”) material can be used as second and third dopants. EL materials include, but are not limited to, small molecule organic fluorescent compounds, luminescent metal complexes, conjugated polymers, and mixtures thereof. Examples of fluorescent compounds include, but are not limited to, chrysenes, pyrenes, perylenes, rubrenes, coumarins, anthracenes, thiadiazoles, derivatives thereof, arylamino derivatives thereof, and mixtures thereof. Examples of metal complexes include, but are not limited to, metal chelated oxinoid compounds, such as tris(8-hydroxyquinolato)aluminum (Alq3); cyclometalated iridium and platinum electroluminescent compounds, such as complexes of iridium with phenylpyridine, phenylquinoline, or phenylpyrimidine ligands as disclosed in Petrov et al., U.S. Pat. No. 6,670,645 and Published PCT Applications WO 03/063555 and WO 2004/016710, and organometallic complexes described in, for example, Published PCT Applications WO 03/008424, WO 03/091688, and WO 03/040257, and mixtures thereof. Examples of conjugated polymers include, but are not limited to poly(phenylenevinylenes), polyfluorenes, poly(spirobifluorenes), polythiophenes, poly(p-phenylenes), copolymers thereof, and mixtures thereof.

Examples of red, orange and yellow light-emitting materials include, but are not limited to, complexes of Ir having phenylquinoline or phenylisoquinoline ligands, periflanthenes, fluoranthenes, and perylenes.

Red light-emitting materials have been disclosed in, for example, U.S. Pat. No. 6,875,524, and published US application 2005-0158577.

In some embodiments, the second and third dopants are cyclometallated complexes of Ir or Pt.

Any of the compounds of Formula I represented by the embodiments, specific embodiments, specific examples, and combination of embodiments discussed above can be used in the photoactive layer.

b. Other Device Layers

The other layers in the device can be made of any materials which are known to be useful in such layers.

The anode 110 is an electrode that is particularly efficient for injecting positive charge carriers. It can be made of, for example materials containing a metal, mixed metal, alloy, metal oxide or mixed-metal oxide, or it can be a conducting polymer, and mixtures thereof. Suitable metals include the Group 11 metals, the metals in Groups 4, 5, and 6, and the Group 8-10 transition metals. If the anode is to be light-transmitting, mixed-metal oxides of Groups 12, 13 and 14 metals, such as indium-tin-oxide, are generally used. The anode may also comprise an organic material such as polyaniline as described in “Flexible light-emitting diodes made from soluble conducting polymer,” Nature vol. 357, pp 477 479 (11 Jun. 1992). At least one of the anode and cathode should be at least partially transparent to allow the generated light to be observed.

The hole injection layer 120 comprises hole injection material and may have one or more functions in an organic electronic device, including but not limited to, planarization of the underlying layer, charge transport and/or charge injection properties, scavenging of impurities such as oxygen or metal ions, and other aspects to facilitate or to improve the performance of the organic electronic device. The hole injection layer can be formed with polymeric materials, such as polyaniline (PANI) or polyethylenedioxythiophene (PEDOT), which are often doped with protonic acids. The protonic acids can be, for example, poly(styrenesulfonic acid), poly(2-acrylamido-2-methyl-1-propanesulfonic acid), and the like.

The hole injection layer can comprise charge transfer compounds, and the like, such as copper phthalocyanine and the tetrathiafulvalene-tetracyanoquinodimethane system (TTF-TCNQ).

In some embodiments, the hole injection layer comprises at least one electrically conductive polymer and at least one fluorinated acid polymer.

In some embodiments, the hole injection layer is made from an aqueous dispersion of an electrically conducting polymer doped with a colloid-forming polymeric acid. Such materials have been described in, for example, published U.S. patent applications US 2004/0102577, US 2004/0127637, US 2005/0205860, and published PCT application WO 2009/018009.

Examples of hole transport materials for layer 130 have been summarized for example, in Kirk-Othmer Encyclopedia of Chemical Technology, Fourth Edition, Vol. 18, p. 837-860, 1996, by Y. Wang. Both hole transporting molecules and polymers can be used. Commonly used hole transporting molecules are: N,N′-diphenyl-N,N′-bis(3-methylphenyl)-[1,1′-biphenyl]-4,4′-diamine (TPD), 1,1-bis[(di-4-tolylamino)phenyl]cyclohexane (TAPC), N,N′-bis(4-methylphenyl)-N,N′-bis(4-ethylphenyl)-[1,1′-(3,3′-dimethyl)biphenyl]-4,4′-diamine (ETPD), tetrakis-(3-methylphenyl)-N,N,N′,N′-2,5-phenylenediamine (PDA), a-phenyl-4-N,N-diphenylaminostyrene (TPS), p-(diethylamino)benzaldehyde diphenylhydrazone (DEH), triphenylamine (TPA), bis[4-(N,N-diethylamino)-2-methylphenyl](4-methylphenyl)methane (MPMP), 1-phenyl-3[p-(diethylamino)styryl]-5-[p-(diethylamino)phenyl]pyrazoline (PPR or DEASP), 1,2-trans-bis(9H-carbazol-9-yl)cyclobutane (DCZB), N,N,N′,N′-tetrakis(4-methylphenyl)-(1,1′-biphenyl)-4,4′-diamine (TTB), N,N′-bis(naphthalen-1-yl)-N,N′-bis-(phenyl)benzidine (—NPB), and porphyrinic compounds, such as copper phthalocyanine. In some embodiments, the hole transport layer comprises a hole transport polymer. In some embodiments, the hole transport polymer is a distyrylaryl compound. In some embodiments, the aryl group has two or more fused aromatic rings. In some embodiments, the aryl group is an acene. The term “acene” as used herein refers to a hydrocarbon parent component that contains two or more ortho-fused benzene rings in a straight linear arrangement. Other commonly used hole transporting polymers are polyvinylcarbazole, (phenylmethyl)-polysilane, and polyaniline. It is also possible to obtain hole transporting polymers by doping hole transporting molecules such as those mentioned above into polymers such as polystyrene and polycarbonate. In some cases, triarylamine polymers are used, especially triarylamine-fluorene copolymers. In some cases, the polymers and copolymers are crosslinkable.

In some embodiments, the hole transport layer further comprises a p-dopant. In some embodiments, the hole transport layer is doped with a p-dopant. Examples of p-dopants include, but are not limited to, tetrafluorotetracyanoquinodimethane (F4-TCNQ) and perylene-3,4,9,10-tetracarboxylic-3,4,9,10-dianhydride (PTCDA).

Examples of electron transport materials which can be used for layer 150 include, but are not limited to, metal chelated oxinoid compounds, including metal quinolate derivatives such as tris(8-hydroxyquinolato)aluminum (AlQ), bis(2-methyl-8-quinolinolato)(p-phenylphenolato)aluminum (BAlq), tetrakis-(8-hydroxyquinolato)hafnium (HfQ) and tetrakis-(8-hydroxyquinolato)zirconium (ZrQ); and azole compounds such as 2-(4-biphenylyl)-5-(4-t-butylphenyl)-1,3,4-oxadiazole (PBD), 3-(4-biphenylyl)-4-phenyl-5-(4-t-butylphenyl)-1,2,4-triazole (TAZ), and 1,3,5-tri(phenyl-2-benzimidazole)benzene (TPBI); quinoxaline derivatives such as 2,3-bis(4-fluorophenyl)quinoxaline; phenanthrolines such as 4,7-diphenyl-1,10-phenanthroline (DPA) and 2,9-dimethyl-4,7-diphenyl-1,10-phenanthroline (DDPA); and mixtures thereof. In some embodiments, the electron transport layer further comprises an n-dopant. N-dopant materials are well known. The n-dopants include, but are not limited to, Group 1 and 2 metals; Group 1 and 2 metal salts, such as LiF, CsF, and Cs₂CO₃; Group 1 and 2 metal organic compounds, such as Li quinolate; and molecular n-dopants, such as leuco dyes, metal complexes, such as W₂(hpp)₄ where hpp=1,3,4,6,7,8-hexahydro-2H-pyrimido-[1,2-a]-pyrimidine and cobaltocene, tetrathianaphthacene, bis(ethylenedithio)tetrathiafulvalene, heterocyclic radicals or diradicals, and the dimers, oligomers, polymers, dispiro compounds and polycycles of heterocyclic radical or diradicals.

An anti-quenching layer may be present between the photoactive layer and the electron transport layer to prevent quenching of blue luminance by the electron transport layer. To prevent energy transfer quenching, the triplet energy of the anti-quenching material has to be higher than the triplet energy of the blue emitter. To prevent electron transfer quenching, the LUMO level of the anti-quenching material has to be shallow enough (with respect to the vacuum level) such that electron transfer between the emitter exciton and the anti-quenching material is endothermic. Furthermore, the HOMO level of the anti-quenching material has to be deep enough (with respect to the vacuum level) such that electron transfer between the emitter exciton and the anti-quenching material is endothermic. In general, anti-quenching material is a large band-gap material with high triplet energy.

In some embodiments, the anti-quenching layer comprises a host material, as discussed above.

In some embodiments, the anti-quenching layer comprises the same host material that is used in the photoactive layer.

Examples of materials for the anti-quenching layer include, but are not limited to, triphenylene, triphenylene derivatives, carbazole, carbazole derivatives, and deuterated analogs thereof. Some specific materials include those shown below.

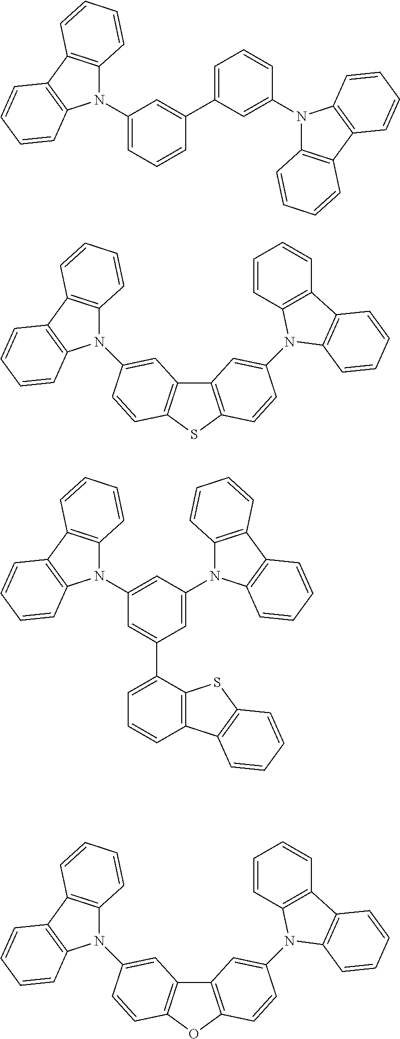

The cathode 160, is an electrode that is particularly efficient for injecting electrons or negative charge carriers. The cathode can be any metal or nonmetal having a lower work function than the anode. Materials for the cathode can be selected from alkali metals of Group 1 (e.g., Li, Cs), the Group 2 (alkaline earth) metals, the Group 12 metals, including the rare earth elements and lanthanides, and the actinides. Materials such as aluminum, indium, calcium, barium, samarium and magnesium, as well as combinations, can be used.

Alkali metal-containing inorganic compounds, such as LiF, CsF, Cs₂O and Li₂O, or Li-containing organometallic compounds can also be deposited between the organic layer 150 and the cathode layer 160 to lower the operating voltage. This layer, not shown, may be referred to as an electron injection layer.

It is known to have other layers in organic electronic devices. For example, there can be a layer (not shown) between the anode 110 and hole injection layer 120 to control the amount of positive charge injected and/or to provide band-gap matching of the layers, or to function as a protective layer. Layers that are known in the art can be used, such as copper phthalocyanine, silicon oxy-nitride, fluorocarbons, silanes, or an ultra-thin layer of a metal, such as Pt. Alternatively, some or all of anode layer 110, active layers 120, 130, 140, and 150, or cathode layer 160, can be surface-treated to increase charge carrier transport efficiency. The choice of materials for each of the component layers is preferably determined by balancing the positive and negative charges in the emitter layer to provide a device with high electroluminescence efficiency.

It is understood that each functional layer can be made up of more than one layer.

c. Device Fabrication

The device layers can be formed by any deposition technique, or combinations of techniques, including vapor deposition, liquid deposition, and thermal transfer.

In some embodiments, the device is fabricated by liquid deposition of the hole injection layer, the hole transport layer, and the photoactive layer, and by vapor deposition of the anode, the electron transport layer, an electron injection layer and the cathode.

The hole injection layer can be deposited from any liquid medium in which it is dissolved or dispersed and from which it will form a film. In some embodiments, the liquid medium consists essentially of one or more organic solvents. In some embodiments, the liquid medium consists essentially of water or water and an organic solvent. The hole injection material can be present in the liquid medium in an amount from 0.5 to 10 percent by weight. The hole injection layer can be applied by any continuous or discontinuous liquid deposition technique. In some embodiments, the hole injection layer is applied by spin coating. In some embodiments, the hole injection layer is applied by ink jet printing. In some embodiments, the hole injection layer is applied by continuous nozzle printing. In some embodiments, the hole injection layer is applied by slot-die coating. After liquid deposition, the liquid medium can be removed in air, in an inert atmosphere, or by vacuum, at room temperature or with heating.

The hole transport layer can be deposited from any liquid medium in which it is dissolved or dispersed and from which it will form a film. In some embodiments, the liquid medium consists essentially of one or more organic solvents. In some embodiments, the liquid medium consists essentially of water or water and an organic solvent. In some embodiments, the organic solvent is an aromatic solvent. In some embodiments, the organic liquid is selected from chloroform, dichloromethane, chlorobenzene, dichlorobenzene, toluene, xylene, mesitylene, anisole, and mixtures thereof. The hole transport material can be present in the liquid medium in a concentration of 0.2 to 2 percent by weight. The hole transport layer can be applied by any continuous or discontinuous liquid deposition technique. In some embodiments, the hole transport layer is applied by spin coating. In some embodiments, the hole transport layer is applied by ink jet printing. In some embodiments, the hole transport layer is applied by continuous nozzle printing. In some embodiments, the hole transport layer is applied by slot-die coating. After liquid deposition, the liquid medium can be removed in air, in an inert atmosphere, or by vacuum, at room temperature or with heating.

The photoactive layer can be deposited from any liquid medium in which it is dissolved or dispersed and from which it will form a film. In some embodiments, the liquid medium consists essentially of one or more organic solvents. In some embodiments, the liquid medium consists essentially of water or water and an organic solvent. In some embodiments, the organic solvent is an aromatic solvent. In some embodiments, the organic solvent is selected from chloroform, dichloromethane, toluene, anisole, 2-butanone, 3-pentanone, butyl acetate, acetone, xylene, mesitylene, chlorobenzene, tetrahydrofuran, diethyl ether, trifluorotoluene, and mixtures thereof. The photoactive material can be present in the liquid medium in a concentration of 0.2 to 2 percent by weight. Other weight percentages of photoactive material may be used depending upon the liquid medium. The photoactive layer can be applied by any continuous or discontinuous liquid deposition technique. In some embodiments, the photoactive layer is applied by spin coating. In some embodiments, the photoactive layer is applied by ink jet printing. In some embodiments, the photoactive layer is applied by continuous nozzle printing. In some embodiments, the photoactive layer is applied by slot-die coating. After liquid deposition, the liquid medium can be removed in air, in an inert atmosphere, or by vacuum, at room temperature or with heating.

The electron transport layer can be deposited by any vapor deposition method. In some embodiments, it is deposited by thermal evaporation under vacuum.

The electron injection layer can be deposited by any vapor deposition method. In some embodiments, it is deposited by thermal evaporation under vacuum.

The cathode can be deposited by any vapor deposition method. In some embodiments, it is deposited by thermal evaporation under vacuum.

### EXAMPLES

The concepts described herein will be further described in the following examples, which do not limit the scope of the invention described in the claims.

### Synthesis Example 1

This example illustrates the synthesis of a compound having Formula I, compound B1.

(i)

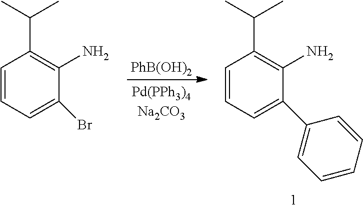 [SMILES: "PhB(OH)2" ; CC(C)c1cccc(Br)c1N ; CC(C)c1cccc(-c2ccccc2)c1N]

Under anaerobic conditions, to the mixture of 2-bromo-6-isopropylaniline derivative (6 g, 28 mmol) in toluene (120 mL) was added phenylboronic acid (5.12 g, 42 mmol, 1.5 eq.) and Pd(PPh₃)₄ (1.62 g, 1.4 mmol, 0.05 eq.), followed by the addition of Na₂CO₃ (8.9 g, 84 mmol, 3 eq., in 40 mL of degassed water) solution. The resultant mixture was stirred at 95° C. overnight under nitrogen. The organic layer was separated and the aqueous layer was extracted with ethyl acetate. The combined organic layers were dried over anhydrous MgSO₄. Filtration, concentration of the filtrate under reduced pressure, and then the silica column chromatography (5-10% ethyl acetate in hexane) provided the desired product 1 (5.2 g, 88%) as a viscous liquid.

(ii)

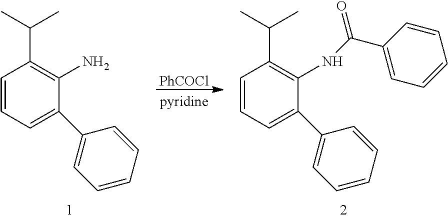 [SMILES: "PhCOCl" ; CC(C)c1cccc(-c2ccccc2)c1N ; CC(C)c1cccc(-c2ccccc2)c1NC(=O)c1ccccc1]

Compound 1 (5 g, 23.6 mmol) and pyridine (5.61 g, 71 mmol, 3 eq.) were dissolved in DCM (80 mL), then benzoyl chloride (4.32 g, 30.76 mmol, 1.3 eq.) was added slowly to the mixture under N₂ at 0° C. (ice/acetone bath). The reaction mixture was stirred for about 3 hrs as the temperature slowly rose to room temperature. The mixture was treated with water, then the organic layer was separated and dried (MgSO₄). After concentration of the filtrate followed by short silica column (10-30% ethyl acetate in hexane) 7.2 g (96% yield) product 2 was obtained as a solid.

(iii)

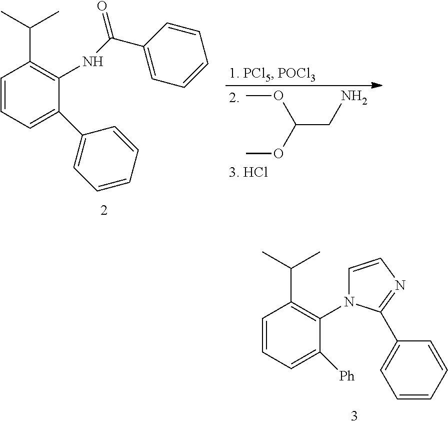

The mixture of starting amide 2 (6.25 g, 19.815 mmol), PCl₅ (4.12 g, 19.81 mmol, 1 eq.), and POCl₃ (40 mL) was refluxed for 3 hrs under nitrogen, then the excessive POCl₃ was distilled off. The mixture of 2,2-dimethoxyethaneamine (20 eq.) in 2-propanol (40 mL) was added to the residue, and the resultant mixture was stirred at room temperature for 4 hrs. Then the conc. HCl (40 mL) was slowly added to the mixture, and the resultant mixture was refluxed overnight The cooled mixture was treated with 2N NaOH to adjust its pH about 10, then treated with ethyl acetate (200 mL). The mixture was passed through a silica bed, and the filtrate was transferred to a separatory funnel to extract organic layer. The separated organic layer was dried (MgSO₄), concentrated, and purified by column chromatography (5-30% ethyl acetate in hexane) to provide 5.2 g (77%) of product 3 as a solid.

(iv)

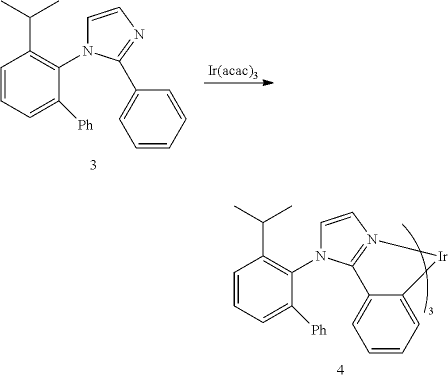

The imidazole derivative 3 (3.5 g, 10.34 mmol) and iridium(III) acetylacetonate (1.01 g, 2.06 mmol) were added to a long neck round-bottom flask and placed in a Kugelrohr. The reaction was purged with nitrogen (3×'s) then heated to 242° C. for 72 hrs. The reaction mixture was allowed to cool to room temperature, dissolved in ethyl acetate, and then purified by silica gel chromatography (0-5, 10, then 15% ethyl acetate in hexane). Concentration of pure fractions provided 2.03 g (83% yield) of product 4 (compound B1) as a yellowish solid.

### Synthesis Example 2

This example illustrates the synthesis of a compound having Formula I, compound B2.

(i)

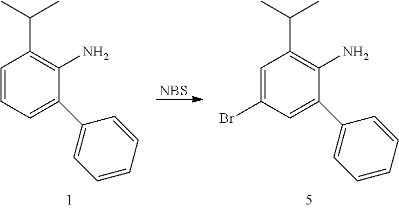

Compound 1 (10.9 g, 51.58 mmol) and NBS (9.18 g, 1 eq.) were dissolved in benzene (80 mL), then the mixture was stirred at room temperature overnight. The precipitated solid was filtered, and the filtrate was concentrated under reduced pressure, then purified by short silica column to provide a desired product 5 (13.5 g, 90%) as a solid.

(ii)

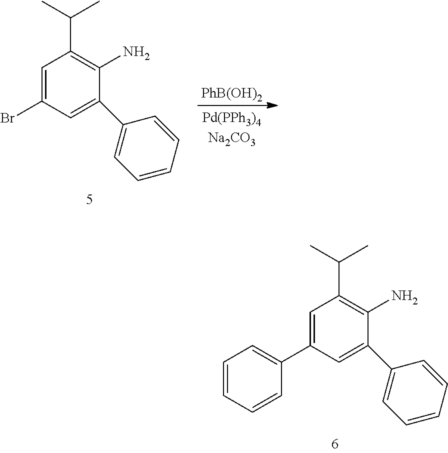 [SMILES: "PhB(OH)2" ; CC(C)c1cc(Br)cc(-c2ccccc2)c1N ; CC(C)c1cc(-c2ccccc2)cc(-c2ccccc2)c1N]

Under anaerobic conditions to the mixture compound 5 (16 g, 55.1 mmol) in the organic solvent (1:1 mixture of toluene and THF, 100 mL) was added phenylboronic acid (10.08 g, 82.7 mmol, 1.5 eq.) and Pd(PPh₃)₄ (3.18 g, 2.7 mmol, 0.05 eq.), followed by the addition of Na₂CO₃ (17.5 g, 165 mmol, 3 eq., in 40 mL of degassed water) solution. The resultant mixture was stirred at 90° C. overnight under nitrogen. The organic layer was separated and the aqueous layer was extracted with ethyl acetate. The combined organic layers were dried over anhydrous MgSO₄. Filtration, concentration of the filtrate under reduced pressure, and then the silica column chromatography (5-10% ethyl acetate in hexane) provided the desired product 6 (8.5 g, 54%) as a solid.

(iii)

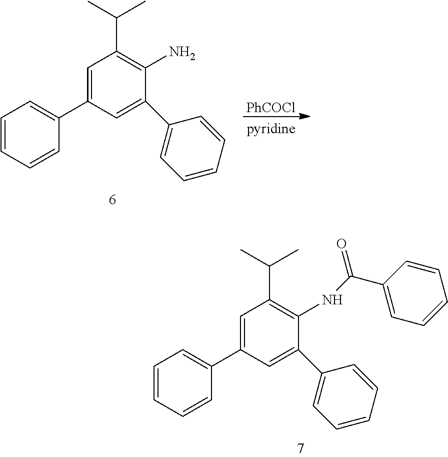 [SMILES: "PhCOCl" ; CC(C)c1cc(-c2ccccc2)cc(-c2ccccc2)c1N ; CC(C)c1cc(-c2ccccc2)cc(-c2ccccc2)c1NC(=O)c1ccccc1]

Compound 6 (7 g, 24.35 mmol) and pyridine (5.78 g, 3 eq.) were dissolved in DCM (80 mL), then benzoyl chloride (4.45 g, 1.3 eq.) was added slowly to the mixture under N₂ at 0° C. (ice/acetone bath). The reaction mixture was stirred for about 3 hrs as the temperature slowly rose to room temperature. The mixture was treated with water, then the organic layer was separated and dried (MgSO₄). After concentration of the filtrate followed by trituration of the residue in the organic solvent (5% ethyl acetate and 5% methylene chloride in hexane) 8.7 g (91% yield) product 7 was obtained as a solid.

(iv)

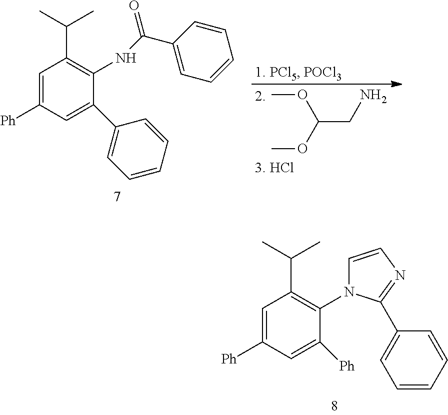

The mixture of starting amide 7 (8.7 g, 22.22 mmol), PCl₅ (4.63 g, 22.22 mmol, 1 eq.), and POCl₃ (45 mL) was refluxed for 3 hrs under nitrogen, then the excessive POCl₃ was distilled off. The mixture of 2,2-dimethoxyethaneamine (46.7 g, 20 eq.) in 2-propanol (50 mL) was added to the residue, and the resultant mixture was stirred at rt for 4 hrs. Then the conc. HCl (50 mL) was slowly added to the mixture, and the resultant mixture was refluxed overnight The cooled mixture was treated with 2N NaOH to adjust its pH about 10, then treated with ethyl acetate (200 mL). The mixture was passed through a silica bed, and the filtrate was transferred to a separatory funnel to extract organic layer. The separated organic layer was dried (MgSO₄), concentrated, and purified by column chromatography (5-30% ethyl acetate in hexane) to provide 6.2 g (67%) of product 8 as a solid.

(v)

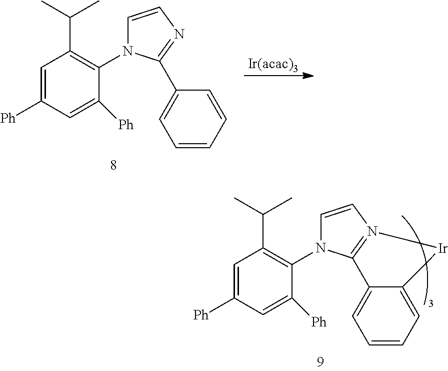

The imidazole derivative 8 (2.4 g, 5.8 mmol) and iridium(III) acetyl acetonate (0.567 g, 1.15 mmol) were added to a long neck round-bottom flask and placed in a Kugelrohr. The reaction was purged with nitrogen (3×'s) then heated to 242° C. for 72 hrs. The reaction mixture was allowed to cool to room temperature, dissolved in ethyl acetate, and then purified by silica gel chromatography (5% ethyl acetate in hexane). Concentration of pure fractions provided 1 g (60% yield) of product 9 (compound B2) as a yellowish solid.

### Synthesis Example 3

This example illustrates the synthesis of a compound having Formula I, compound B3.

(i)

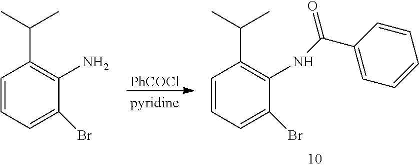 [SMILES: "PhCOCl" ; CC(C)c1cccc(Br)c1N ; CC(C)c1cccc(Br)c1NC(=O)c1ccccc1]

To a 250 mL RBF containing 2-bromo-6-isopropylaniline (3.5 g, 16.34 mmol) and pyridine (3.87 g, 3 eq.) in methylene chloride (100 mL) was added benzoyl chloride (2.98 g, 1.3 eq.) dropwise at 0° C. under nitrogen. The mixture was stirred overnight as the reaction temperature gradually rose to room temperature. The mixture was treated with water, then the organic layer was separated and dried (MgSO₄). After concentration of the filtrate followed by recrystallization (ethyl acetate and hexane), 4.05 g of product 10 was obtained as a solid (78%).

(ii)

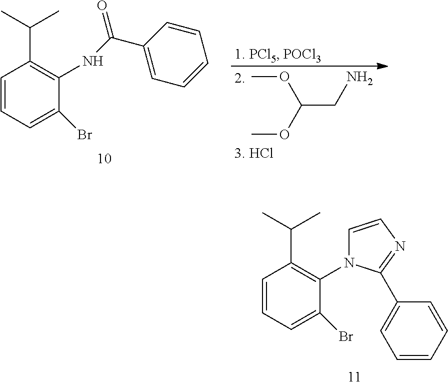

The mixture of compound 10 (4.05 g, 12.72 mmol), PCl₅ (2.65 g, 1 eq.), and POCl₃ (40 mL) was refluxed for 3 hrs under nitrogen, then the excessive POCl₃ was distilled off. The mixture of 2,2-dimethoxyethaneamine (20 eq.) in 2-propanol (40 mL) was added to the residue, and the resultant mixture was stirred at rt for 4 hrs. Then the conc. HCl (40 mL) was slowly added to the mixture, and the resultant mixture was refluxed overnight The cooled mixture was treated with 2N NaOH to adjust its pH about 10, then treated with ethyl acetate (200 mL). The mixture was passed through a Silica bed, and the filtrate was transferred to a separatory funnel to extract organic layer. The combined organic layer was dried (MgSO₄), concentrated, and purified by column chromatography (5-30% ethyl acetate in hexane) to afford the product 11 as a solid (3.08 g, 71%).

(iii)

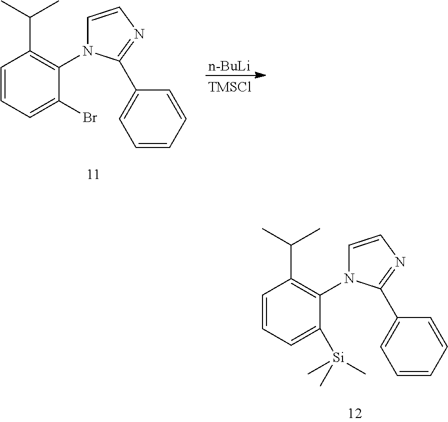

To the solution compound 11 (4.1 g, 12.01 mmol) in THF (100 mL) was slowly added n-BuLi (7.5 mL, 1.6M, 1 eq.) dropwise while maintaining internal temperature below −72° C. under nitrogen. After 1 hr at −72° C., trimethylsilylchloride solution (TMSCl (1.3 g, 1 eq.) in 5 mL of THF, prepared in a dry box) was added dropwise at −72° C. After stirring the mixture for 1 hr at −72° C., the resultant mixture was stirred for another 2 hrs as the temperature slowly rose to rt. The mixture was treated with ethyl acetate and water, then the organic layer was separated and dried (MgSO₄). Concentration of the filtrate followed by chromatography provided 2.6 g (65% yield) of product 12 as a solid.

(iv)

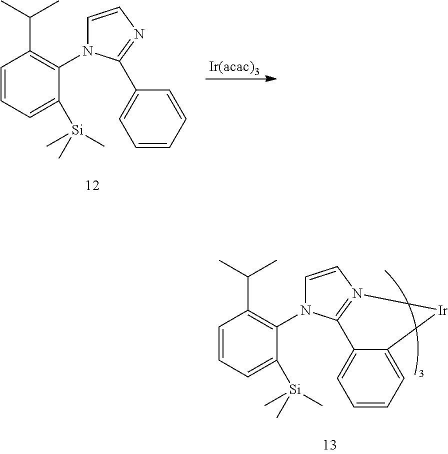

Compound 12 (1.1 g, 3.29 mmol) and Ir(acac)₃ (0.32 g, 0.657 mmol) were mixed together into the Kugelrohr reaction flask. The container having mixture was vacuumed and refilled with nitrogen repeatedly three times, then it was rotated under nitrogen at 243° C. for 3 days. The reaction mixture was allowed to cool to room temperature, dissolved in ethyl acetate, and then purified by silica gel chromatography (3-4% ethyl acetate in hexane). Concentration of pure fractions provided 0.12 g (15% yield) of product 13 (compound B3) as a yellowish solid.

### Synthesis Example 4

This example illustrates the synthesis of a compound having Formula I, compound B4.

(i)

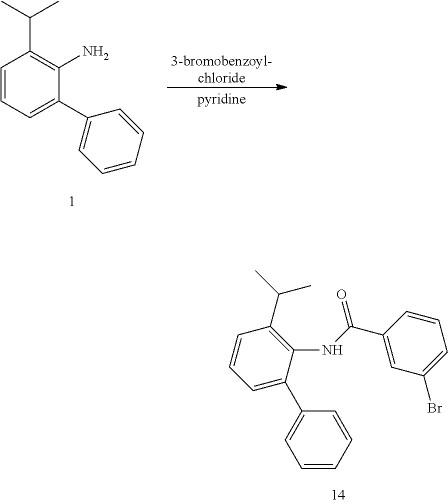 [SMILES: CC(C)c1cccc(-c2ccccc2)c1N ; "3-bromobenzoyl-chloride" ; "pyridine" ; CC(C)c1cccc(-c2ccccc2)c1NC(=O)c1cccc(Br)c1]

To a 250 mL RBF containing compound 1 (3.8 g, 17.98 mmol) and pyridine (4.26 g, 3 eq.) in methylene chloride (100 mL) was added 3-bromobenzoyl chloride (5.13 g, 1.3 eq.) dropwise at 0° C. under nitrogen. The mixture was stirred overnight as the reaction temperature gradually rose to room temperature. The mixture was treated with water, then the organic layer was separated and dried (MgSO₄). After concentration of the filtrate followed by recrystallization (ethyl acetate and hexane), 3.5 g of product 14 was obtained as a solid (49%).

(ii)

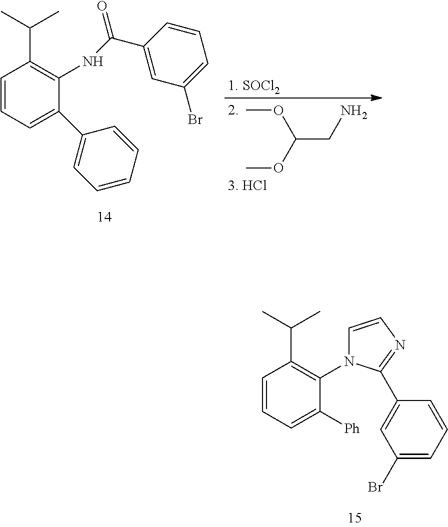

The mixture of compound 14 (3.38 g, 8.59 mmol) and 15 mL of SOCl₂ was refluxed (oil bath temp: 96° C.) for 3 hrs. Excess thionyl chloride was removed by house vacuum distillation followed by high vacuum. The residue was treated with the mixture of 25 mL of 2,2-dimethoxyethaneamine and 25 mL of isopropanol for 2 hrs at rt. Then about 30 mL of conc. HCl was slowly added to the mixture. The resultant mixture was refluxed (oil bath temp: 105° C.) overnight. The mixture was cooled to rt then treated with 2M NaOH solution to be basic (pH10), then treated with ethyl acetate. The mixture was passed through silica bed. The organic layer was separated from the filtrate, dried on MgSO₄, then concentrated. By column chromatography (5% ethyl acetate in hexane) 3.1 g (86%) of product 15 was obtained as a white solid.

(iii)

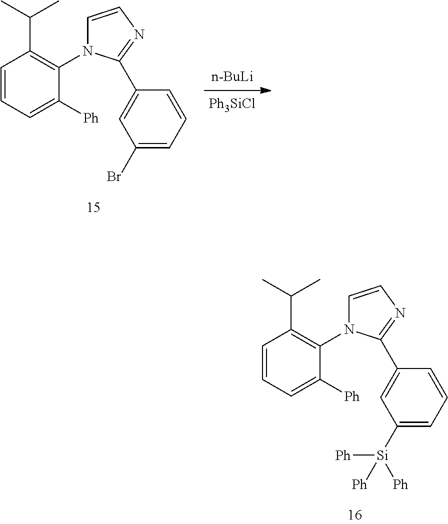

Compound 15 (2 g, 4.79 mmol) was treated with nBuLi (1.6M, 1 eq. 3 mL) at −78° C. by dropwise addition under N₂. After 30 min at −78° C., triphenylsilyl chloride (1.41 g, 1 eq.) in THF (10 mL) was added dropwise. The reaction mixture was continuously stirred as the temperature slowly rose to rt. The reaction mixture was treated with ethyl acetate and water, and the organic layer was separated and dried (MgSO₄). Concentration of the filtrate followed by chromatography purification provided a desired product 16 (0.8 g, 28% yield) as a white solid.

(iv)

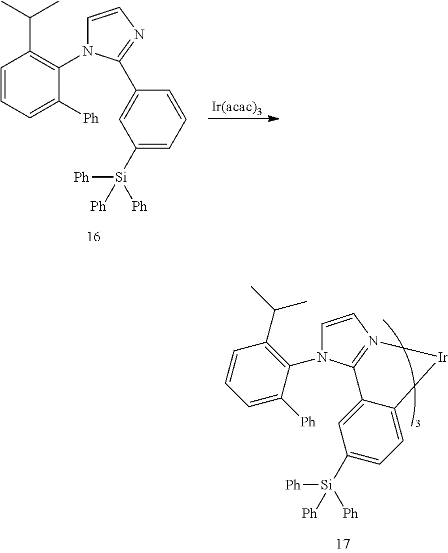

Compound 16 (0.77 g, 1.29 mmol, 3.2 eq.) and Ir(acac)₃ (0.398 mmol, 0.195 g) were reacted in a pressure reactor tube at 250° C. (300 psi) for 3 days. The reaction mixture was allowed to cool to room temperature, dissolved in ethyl acetate, and then purified by silica gel chromatography (3-4% ethyl acetate in hexane). Concentration of pure fractions provided 0.24 g (30% yield) of product 17 (compound B4) as a yellowish solid.

### Synthesis Example 5

This example illustrates the synthesis of a compound having Formula I, compound B5.

(i)

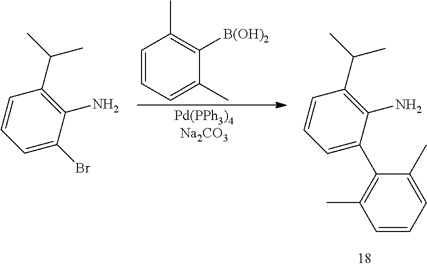 [SMILES: CC(C)c1cccc(Br)c1N ; Cc1cccc(C)c1B(O)O ; Cc1cccc(C)c1-c1cccc(C(C)C)c1N]

Under anaerobic conditions to the solution of 2-bromo-6-isopropylaniline (6 g, 28.02 mmol) in toluene (100 mL) was added 2,6-dimethylphenylboronic acid (4.2 g, 28.02 mmol) solution in EtOH (60 mL), followed by the addition of Pd(PPh₃)₄ (1.62 g, 0.05 eq.) and Na₂CO₃ (8.9 g in 40 mL of degassed water) solution. The resultant mixture was stirred at 85° C. for 18 hrs under nitrogen. The organic layer was separated and the aqueous layer was extracted with ethyl acetate. The combined organic layers were dried over anhydrous MgSO₄. Filtration, concentration of the filtrate, and then the silica column chromatography (5-20% ethyl acetate in hexane) provided the desired product 18 (5.36 g, 80%).

(ii)

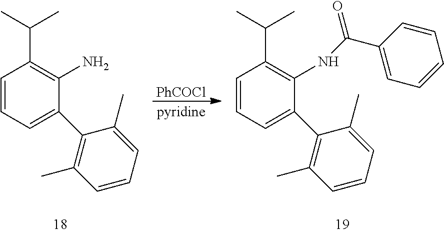 [SMILES: "PhCOCl" ; Cc1cccc(C)c1-c1cccc(C(C)C)c1N ; "pyridine" ; Cc1cccc(C)c1-c1cccc(C(C)C)c1NC(=O)c1ccccc1]

To a 250 mL RBF containing compound 18 (3.91 g, 16.34 mmol) and pyridine (3.87 g, 3 eq.) in methylene chloride (100 mL) was added benzoyl chloride (2.98 g, 1.3 eq.) dropwise at 0° C. under nitrogen. The mixture was stirred overnight as the reaction temperature gradually rose to room temperature. The mixture was treated with water, then the organic layer was separated and dried (MgSO₄). After concentration of the filtrate followed by recrystallization (ethyl acetate and hexane), 5.05 g of product 19 was obtained as a solid (90%).

(iii)

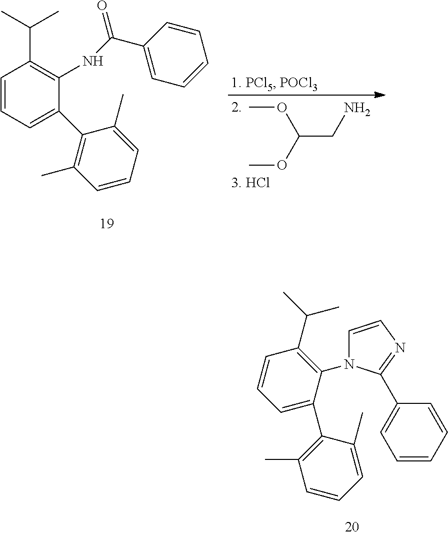

The mixture of compound 19 (6.2 g, 18.05 mmol), PCl₅ (3.75 g, 18.05 mmol, 1 eq.), and POCl₃ (40 mL) was refluxed for 3 hrs under nitrogen, then the excessive POCl₃ was distilled off. The mixture of 2,2-dimethoxyethaneamine (20 eq.) in 2-propanol (40 mL) was added to the residue, and the resultant mixture was stirred at rt for 4 hrs. Then the conc. HCl (40 mL) was slowly added to the mixture, and the resultant mixture was refluxed overnight The cooled mixture was treated with 2N NaOH to adjust its pH about 10, then treated with ethyl acetate (200 mL).

The mixture was passed through a Silica bed, and the filtrate was transferred to a separatory funnel to extract organic layer. The combined organic layer was dried (MgSO₄), concentrated, and purified by column chromatography (5-30% ethyl acetate in hexane). Concentration of pure fractions provided a product 20 as a white solid (3.5 g, 53%).

(iv)

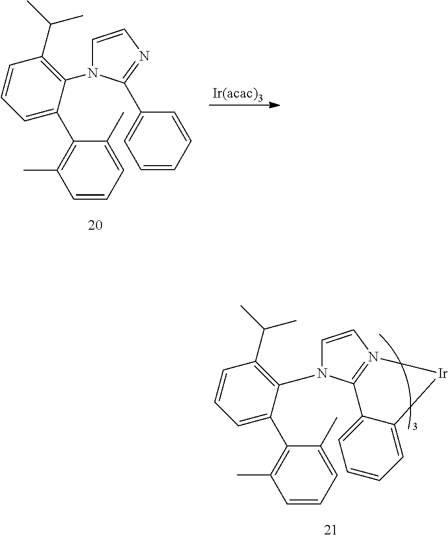

The starting compound 20, (3.2 g g, 8.73 mmol, 5 eq.) and iridium(III) acetyl acetonate (0.854 g, 1.74 mmol) were added to a long neck round-bottom flask and placed in a Kugelrohr. The reaction was purged with nitrogen (3×'s) then heated to 242° C. for 72 hrs. The reaction was allowed to cool to room temperature, dissolved in ethyl acetate, and then purified by silica gel chromatography (0-5, 10, then 15% ethyl acetate/hexane). Concentration of pure fractions provided 1.66 g (74%) of product 21 (compound B5) as a yellowish solid.

### Synthesis Example 6

This example illustrates the synthesis of a compound having Formula I, compound B6.

(i)

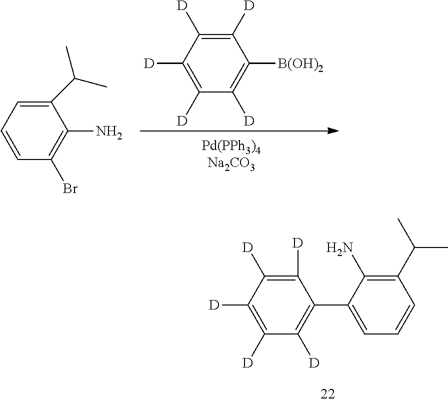 [SMILES: CC(C)c1cccc(Br)c1N ; [2H]c1c([2H])c([2H])c(B(O)O)c([2H])c1[2H] ; [2H]c1c([2H])c([2H])c(-c2cccc(C(C)C)c2N)c([2H])c1[2H]]

Under anaerobic conditions to the mixture of 2-bromo-6-isopropylaniline derivative (6 g, 28 mmol) in toluene (200 mL) was added dphenyl-d₅-boronic acid (5.3 g, 42 mmol, 1.5 eq.) and Pd(PPh₃)₄ (2.6 g, 0.08 eq.), followed by the addition of Na₂CO₃ (22 g, 7.5 eq., in 60 mL of degassed water) solution. The resultant mixture was stirred at 100° C. overnight under nitrogen. The organic layer was separated and the aqueous layer was extracted with ethyl acetate. The combined organic layers were dried over anhydrous MgSO₄. Filtration, concentration of the filtrate under reduced pressure, and then the silica column chromatography (5-10% ethyl acetate in hexane) provided the desired product 22 (5.1 g, 84%) as a viscous liquid.

(ii)

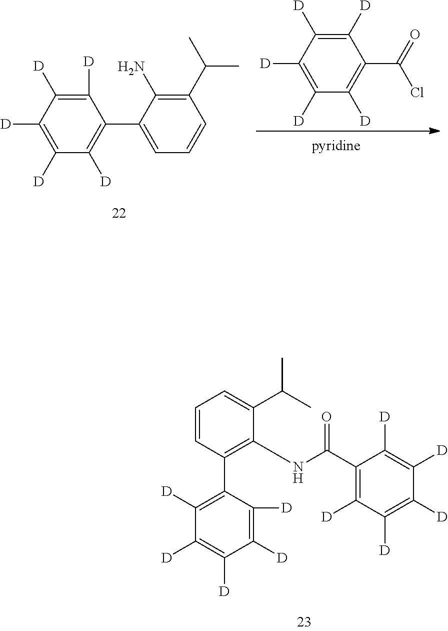

Compound 22 (5 g, 23.1 mmol) and pyridine (5.5 g, 3 eq.) were dissolved in DCM (80 mL), then d₅-benzoyl chloride (4.37 g, 1.3 eq.) was added slowly to the mixture under N₂ at 0° C. (ice/acetone bath). The reaction mixture was stirred for 2 days as the temperature slowly rose to room temperature. The mixture was treated with water, then the organic layer was separated and dried (MgSO₄). After concentration of the filtrate followed by short silica column (10-30% ethyl acetate in hexane) 2.5 g (33% yield) product 23 was obtained as a solid.

(iii)

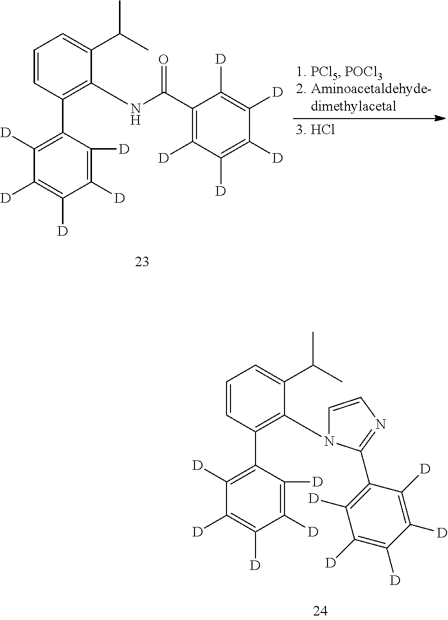 [SMILES: [2H]c1c([2H])c([2H])c(C(=O)Nc2c(-c3c([2H])c([2H])c([2H])c([2H])c3[2H])cccc2C(C)C)c([2H])c1[2H] ; [2H]c1c([2H])c([2H])c(-c2cccc(C(C)C)c2-n2ccnc2-c2c([2H])c([2H])c([2H])c([2H])c2[2H])c([2H])c1[2H]]

The mixture of compound 23 (2.47 g, 7.59 mmol), PCl₅ (1.58 g, 1 eq.), and POCl₃ (22 g) was refluxed for 3 hrs under nitrogen, then the excessive POCl₃ was distilled off. The mixture of 2,2-dimethoxyethaneamine (20 eq.) in 2-propanol (24 mL) was added to the residue, and the resultant mixture was stirred at rt for 4 hrs. Then the conc. HCl (18 mL) was slowly added to the mixture, and the resultant mixture was refluxed overnight The cooled mixture was treated with 2N NaOH to adjust its pH about 10, then treated with ethyl acetate (200 mL). The mixture was passed through a silica bed, and the filtrate was transferred to a separatory funnel to extract organic layer. The separated organic layer was dried (MgSO₄), concentrated, and purified by column chromatography (5-30% ethyl acetate in hexane) to provide 2.0 g (76%) of product 24 as a solid.

(iv)

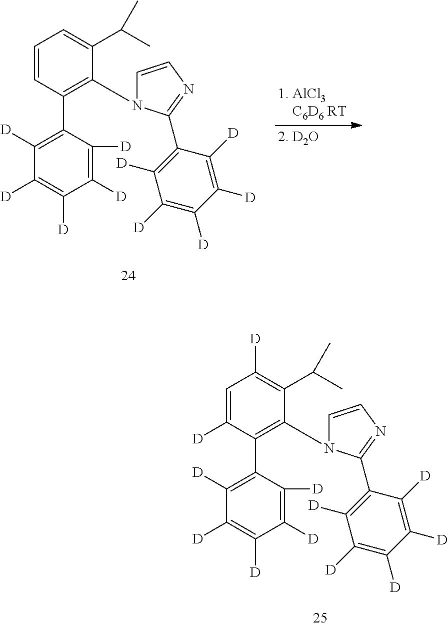 [SMILES: [2H]c1c([2H])c([2H])c(-c2cccc(C(C)C)c2-n2ccnc2-c2c([2H])c([2H])c([2H])c([2H])c2[2H])c([2H])c1[2H] ; [2H]c1cc([2H])c(C(C)C)c(-n2ccnc2-c2c([2H])c([2H])c([2H])c([2H])c2[2H])c1-c1c([2H])c([2H])c([2H])c([2H])c1[2H]]

In the glove box, compound 24 (2 g, 5.74 mmol) was dissolved 110 mL of benzene-d₆, followed by the addition of aluminum trichloride (1.15 g, 1.5 eq.) in one portion. The reaction mixture was stirred at room temperature for 5 days, then quenched with D₂O by stirring for 30 mins. The mixture was extracted with ethyl acetate and the separated organic layer was dried (MgSO₄). Concentration of the filtrate provided a desired product 25 (1.5 g, 75%) as a solid.

(v)

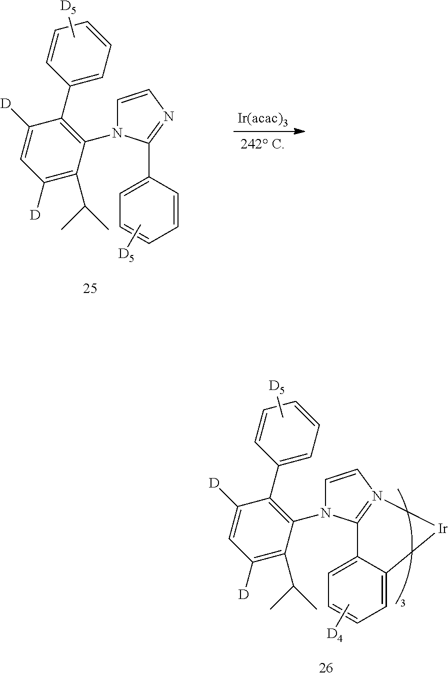

The compound 25 (1.5 g, 4.28 mmol, 5 eq.) and iridium(III) acetylacetonate (0.42 g, 0.855 mmol) were added to a long neck round-bottom flask and placed in a Kugelrohr. The reaction was purged with nitrogen (3×'s) then heated to 242° C. for 72 hrs. The reaction was allowed to cool to room temperature, dissolved in ethylacetate, and then purified by silica gel chromatography (0-5, 10, then 15% ethyl acetate inhexane). Concentration of pure fractions provided 0.15 g (14%) of product 26 (compound B6) as a yellowish solid.

### Device Examples

These examples demonstrate the fabrication and performance of OLED devices.

### (1) Materials

HIJ-1 is an electrically conductive polymer doped with a polymeric fluorinated sulfonic acid. Such materials have been described in, for example, published U.S. patent applications US 2004/0102577, US 2004/0127637, US 2005/0205860, and published PCT application WO 2009/018009.
HT-1 is a triarylamine-containing polymer. Such materials have been described in, for example, published PCT application WO 2009/067419.
Host-1 the carbazole derivative shown below.

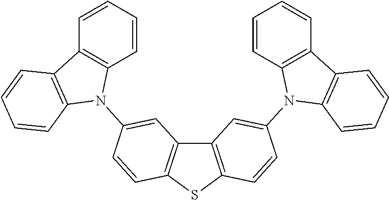 [SMILES: c1ccc2c(c1)c1ccccc1n2-c1ccc2sc3ccc(-n4c5ccccc5c5ccccc54)cc3c2c1]

Host-2 is the carbazole derivative shown below

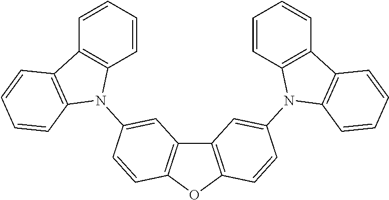 [SMILES: c1ccc2c(c1)c1ccccc1n2-c1ccc2oc3ccc(-n4c5ccccc5c5ccccc54)cc3c2c1]

ET-1 is a metal quinolate complex.
   Comparative compound A-1, shown below, can be made as described in published US application US 2011/0057599.

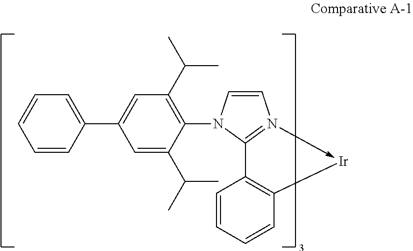

The devices had the following structure on a glass substrate:
anode=Indium Tin Oxide (ITO), 50 nm
hole injection layer=HIJ-1 (50 nm)
hole transport layer=HT-1 (20 nm)
photoactive layer, discussed below=86:14 Host-1:dopant (43 nm);
anti-quenching layer=Host-1 (10 nm)
electron transport layer=ET-1 (10 nm)
electron injection layer/cathode=CsF/Al ( 1/100 nm)

### (2) Device Fabrication

OLED devices were fabricated by a combination of solution processing and thermal evaporation techniques. Patterned indium tin oxide (ITO) coated glass substrates from Thin Film Devices, Inc were used. These ITO substrates are based on Corning 1737 glass coated with ITO having a sheet resistance of 30 ohms/square and 80% light transmission. The patterned ITO substrates were cleaned ultrasonically in aqueous detergent solution and rinsed with distilled water. The patterned ITO was subsequently cleaned ultrasonically in acetone, rinsed with isopropanol, and dried in a stream of nitrogen.

Immediately before device fabrication the cleaned, patterned ITO substrates were treated with UV ozone for 10 minutes. Immediately after cooling, an aqueous dispersion of HIJ-1 was spin-coated over the ITO surface and heated to remove solvent. After cooling, the substrates were then spin-coated with a hole transport solution, and then heated to remove solvent. The substrates were masked and placed in a vacuum chamber. The photoactive layer, the electron transport layer and the anti-quenching layer were deposited by thermal evaporation, followed by a layer of CsF. Masks were then changed in vacuo and a layer of Al was deposited by thermal evaporation. The chamber was vented, and the devices were encapsulated using a glass lid, desiccant, and UV curable epoxy.

### (3) Device Characterization

The OLED samples were characterized by measuring their (1) current-voltage (I-V) curves, (2) electroluminescence luminance versus voltage, and (3) electroluminescence spectra versus voltage. All three measurements were performed at the same time and controlled by a computer. The current efficiency of the device at a certain voltage is determined by dividing the electroluminescence luminance of the LED by the current density needed to run the device. The unit is a cd/A. The color coordinates were determined using either a Minolta CS-100 meter or a Photoresearch PR-705 meter.

### Examples 1 and 2 and Comparative Example A

These examples illustrate the use of compounds having Formula I as the light emitting material in a device.

In Example 1, the dopant was compound B1.

In Example 2, the dopant was compound B2.

In Comparative Example A, the dopant was comparative compound A-1.

The materials used and the results are given in Table 1 below.

TABLE 1
Device results

| | | | | | Voltage | | |
|---|---|---|---|---|---|---|---|
| | | Peak | | | @ 20 | | |
| Exam- | | Emission | CIE | EQE | mA/cm2 | PLQE | T70, |
| ple | Dopant | (nm) | (x, y) | (%) | (V) | (%) | hrs |
| 1 | B1 | 478 | (.184, | 18.1 | 8.4 | 93.4 | 780 |
| | | | .396) | | | | |
| 2 | B2 | 480 | (.196, | 16.8 | 9.4 | 95.3 | 300 |
| | | | .406) | | | | |
| Comp. | A-1 | 473 | (.179, | 16.5 | 10.4 | 93.0 | 600 |
| A | | | .360) | | | | |

All data @ 1000 nits. CIE(x, y) are the x and y color coordinates according to the C.I.E. chromaticity scale (Commission Internationale de L'Eclairage, 1931); EQE is the external quantum efficiency; PLQE is photoluminescence quantum efficiency; T70 is the time, in hours, to reach 70% of the initial luminance.

It can be seen from Table 1 that the voltage is significantly lower when the compound of Formula I is present as the dopant, compared to comparative compound A-1. Comparative compound A-1 has two identical alkyl ortho substituents on the N-phenyl group on the imidazole group.

### Examples 3 to 6

These examples illustrate the use of compounds having Formula I as the light emitting material in a device.

In Example 3, the dopant was compound B3.

In Example 4, the dopant was compound B4.

In Example 5, the dopant was compound B5.

In Example 6, the dopant was compound B6.

TABLE 2
Device results

| | | | | | Voltage | | |
|---|---|---|---|---|---|---|---|
| | | Peak | | | @ 20 | | |
| Exam- | | Emission | CIE | EQE | mA/cm2 | PLQE | T70, |
| ple | Dopant | (nm) | (x, y) | (%) | (V) | (%) | hrs |
| 3 | B3 | 472 | (.18, | 17.30 | 7.9 | 89.1 | 40 |
| | | | .353) | | | | |
| 4 | B4 | 474 | (.19, | 18.60 | 9.8 | 96.5 | 240 |
| | | | .388) | | | | |
| 5 | B5 | 482 | (.203, | 19.90 | 10.2 | 92.7 | 500 |
| | | | .467) | | | | |
| 6 | B6 | 477 | (.184, | 19.10 | 8.8 | 94.4 | 200 |
| | | | .395) | | | | |

All data @ 1000 nits. CIE(x, y) are the x and y color coordinates according to the C.I.E. chromaticity scale (Commission Internationale de L'Eclairage, 1931); EQE is the external quantum efficiency; PLQE is photoluminescence quantum efficiency; T70 is the time, in hours, to reach 70% of the initial luminance.

As can be seen in Table 2, all the compounds are shown to produce blue electroluminescence with high efficiency. Further purification and device optimization should enhance device performance.

### Example 7

This example illustrates the use of a compound having Formula I as the light emitting material in a device.

A device was made as described above, except that Host-2 was used as a host. The dopant was compound B1. The device results are shown in Table 3.

TABLE 3
Device Results

| | | | | | Voltage | | |
|---|---|---|---|---|---|---|---|
| | | Peak | | | @ 20 | | |
| Exam- | | Emission | CIE | EQE | mA/cm2 | PLQE | T70, |
| ple | Dopant | (nm) | (x, y) | (%) | (V) | (%) | hrs |
| 7 | B1 | 477 | (.187, | 22.7 | 7.8 | 93.4 | 1250 |
| | | | .379) | | | | |

All data @ 1000 nits. CIE(x, y) are the x and y color coordinates according to the C.I.E. chromaticity scale (Commission Internationale de L'Eclairage, 1931); EQE is the external quantum efficiency; PLQE is photoluminescence quantum efficiency; T70 is the time, in hours, to reach 70% of the initial luminance.

As can be seen in Table 3, the device had blue electroluminescence, high efficiency, and improved lifetime.

Note that not all of the activities described above in the general description or the examples are required, that a portion of a specific activity may not be required, and that one or more further activities may be performed in addition to those described. Still further, the order in which activities are listed are not necessarily the order in which they are performed.

In the foregoing specification, the concepts have been described with reference to specific embodiments. However, one of ordinary skill in the art appreciates that various modifications and changes can be made without departing from the scope of the invention as set forth in the claims below. Accordingly, the specification and figures are to be regarded in an illustrative rather than a restrictive sense, and all such modifications are intended to be included within the scope of invention.

Benefits, other advantages, and solutions to problems have been described above with regard to specific embodiments. However, the benefits, advantages, solutions to problems, and any feature(s) that may cause any benefit, advantage, or solution to occur or become more pronounced are not to be construed as a critical, required, or essential feature of any or all the claims.

It is to be appreciated that certain features are, for clarity, described herein in the context of separate embodiments, may also be provided in combination in a single embodiment. Conversely, various features that are, for brevity, described in the context of a single embodiment, may also be provided separately or in any subcombination. Further, reference to values stated in ranges include each and every value within that range.

What is claimed is:

1. A compound having Formula I 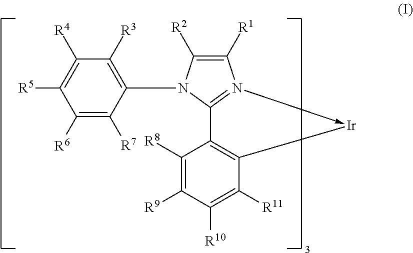
wherein:
R¹, R², R⁴, R⁶, and R⁸-R¹¹ are the same or different and are selected from the group consisting of H, D, alkyl, deuterated alkyl, silyl, and deuterated silyl;
R³ and R⁷ are selected from the group consisting of alkyl, deuterated alkyl, aryl, deuterated aryl, silyl, and deuterated silyl;
R⁵ is selected from the group consisting of H, D, alkyl, deuterated alkyl, silyl, deuterated silyl, aryl, and deuterated aryl;
with the proviso that R³ is not the same as R⁷.

2. The compound of claim 1, wherein one of R³ and R⁷ is selected from the group consisting of alkyl or deuterated alkyl, and the other of R³ and R⁷ is selected from the group consisting of silyl, hydrocarbon aryl, and deuterated analogs thereof.

3. The compound of claim 1, wherein one of R³ and R⁷ is a secondary alkyl or deuterated secondary alkyl having 3-12 carbons.

4. The compound of claim 1, wherein one of R³ and R⁷ is selected from the group consisting of phenyl, biphenyl, napthyl, and deuterated analogs thereof, wherein any of the previous groups may have one or more substituents that are alkyl groups with 1-10 carbons.

5. The compound of claim 1, wherein one of R³ and R⁷ is selected from the group consisting of silyl and deuterated silyl.

6. The compound of claim 1, wherein R¹ and R² are H or D.

7. The compound of claim 1, wherein R⁴-R⁶ are H or D.

8. The compound of claim 1, wherein R⁸-R¹¹ are H or D.

9. The compound of claim 1, wherein at least one of R¹, R², R⁴-R⁶, and R⁸-R¹¹ is not H or D.

10. The compound of claim 1, wherein the compound is at least 10% deuterated.

11. A compound selected from compound B1 through B12.

12. An organic electronic device comprising a first electrical contact, a second electrical contact and a photoactive layer therebetween, the photoactive layer comprising a compound having Formula I 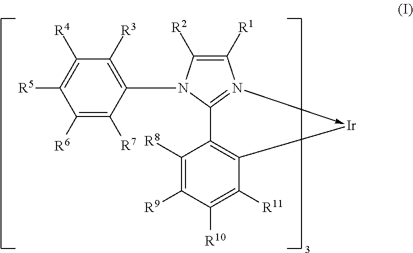
wherein:
R¹, R², R⁴, R⁶, and R⁸-R¹¹ are the same or different and are selected from the group consisting of H, D, alkyl, deuterated alkyl, silyl, and deuterated silyl;
R³ and R⁷ are selected from the group consisting of alkyl, deuterated alkyl, aryl, deuterated aryl, silyl, and deuterated silyl;
R⁵ is selected from the group consisting of H, D, alkyl, deuterated alkyl, silyl, deuterated silyl, aryl, and deuterated aryl;
with the proviso that R³ is not the same as R⁷.

13. The device of claim 12, wherein the photoactive layer comprises the electroactive compound of Formula I and further comprises a host material.

14. The device of claim 13, wherein the photoactive layer consists essentially of the electroactive compound of Formula I and a host material.

15. The device of claim 13, wherein the host material has Formula a
Ar(Cz)ₙ Formula a
where:
Ar is an aryl group, or a deuterated analog thereof;
Cz represents N-carbazolyl, diphenyl-N-carbazolyl, or a deuterated analog thereof; and
n is an integer from 1-4.

16. The device of claim 15, wherein Ar is selected from the group consisting of biphenyl, terphenyl, triphenylene, phenanthrene, fluorene, chrysene, dibenzothiophene, dibenzofuran, pyridine, pyridazine, pyridmidine, pyrazine, triazine, benzimidazole, benzothiazole, quinoline, isoquinoline, benzofuropyridein, furodipyridine, benzothienopyridie, thienodipyridine, and deuterated analogs thereof.
